(19) United States
(12) Patent Application Publication
(10) Pub. No.: US 2009/0126980 A1
(43) Pub. Date: May 21, 2009

(54) PRINTED WIRING BOARD

(76) Inventor: Eiji Katsuta, Aichi (JP)

Correspondence Address: MORGAN LEWIS & BOCKIUS LLP, 1111 PENNSYLVANIA AVENUE NW, WASHINGTON, DC, 20004, US

(21) Appl. No.: 12/265,156

(22) Filed: Nov. 5, 2008

(30) Foreign Application Priority Data
Nov. 7, 2007 (JP) 2007-289880

(51) Int. Cl. H05K 1/16

(52) U.S. Cl. 174/260

(57) ABSTRACT

In a printed wiring board, contacts are formed only on one side surface of a printed board, and electronic components are arranged only on the other side surface of the printed board. Then, soldering work employing Pb free solder is conducted only on the other side surface of the printed board on which the electronic components are arranged, and thus, the electronic components are mounted.

### BACKGROUND OF THE INVENTION

The present invention relates to a printed wiring board on which soldering work employing Pb free solder can be reliably conducted.

On occasion of mounting electronic components on a surface of a printed board, flow soldering or reflow soldering have been generally conducted. The flow soldering is conducted in the following manner. The printed board to which the electronic components have been bonded is brought into contact with melted solder, by soaking the printed board in a surface layer of a solder tank containing the solder in a liquid state which has been heated and melted, thereby to fix the electronic components to the printed board by soldering. The reflow soldering is conducted in the following manner. Cream solder which contains flux in a paste state is printed on the printed board in advance, and the printed board having the electronic components arranged on a surface of this cream solder is heated with a hot blast in a reflow furnace, whereby the cream solder is melted and the electronic components are fixed to the printed board by soldering. As shown in FIGS. 8A and 8B, not only electronic components 104 but also contacts 102 to be used as switches are provided on a printed board 110 (Reference should be made to JP2003-249727A, for example).

Before the electronic components 104 are fixed by soldering to the printed board 110 on which the above described contacts 102 are provided, a film of strippable solder resist is formed so as to cover the contacts 102 for preventing flux or the like from adhering to the contacts. The flux or the like is applied for the purpose of removing an oxide film which is formed on a bonding surface between the electronic components 104 and the printed board 110. This strippable solder resist can be peeled off from the printed board 110 without leaving residue, after the solder has been heated, and removed from the printed board 110 by means of a pair of tweezers or the like.

By the way, Sn—Pb eutectic solder which contains Pb, for example, has been conventionally used as material for the solder. However, considering environment protection, it has been recently required to use the Pb free solder in which the Pb is not contained, as the material for the solder. In case where the Pb free solder is used as the material for the solder in place of the Sn—Pb eutectic solder, it has become necessary to set a heating temperature for melting the solder to be higher than before, because a melting temperature of the Pb free solder is higher than the melting temperature of the conventional solder which contains the Pb.

However, according to an experiment carried out by the applicant of this application, it has been found that the strippable solder resist is hardened and cannot be removed at the heating temperature for melting the above described Pb free solder. For this reason, a printed wiring board in which the strippable solder resist is not used or the strippable solder resist is not hardened has been requested. Specifically, such a printed wiring board that even though the Pb free solder is used, the electronic components can be mounted thereon, while adhesion of the flux or the like to the contacts is restrained, has been requested.

### SUMMARY OF THE INVENTION

The invention has been made in view of such circumstances, and it is an object of the invention to provide a printed wiring board on which electronic components can be mounted, while adhesion of flux or the like to contacts is restrained, even in case where Pb free solder is used.

In order to achieve the object, the present invention provides the following arrangements.

(1) A printed wiring board comprising:

a printed board having a first surface and a second surface opposed to the first surface;

contacts which are to be used as switches and are only formed on the first surface;

electronic components which are arranged only on the second surface and mounted by conducting soldering work employing Pb free solder on the second surface.

(2) The printed wiring board according to (1), wherein

one of the electronic components is an LED,

a through hole is formed through the printed board,

the LED is inserted into the through hole in such a manner that light is emitted from the first surface, and

the soldering work employing the Pb free solder is conducted only on the second surface.

(3) The printed wiring board according to (1), wherein a film of strippable solder resist is formed on the contacts, and the soldering work employing the Pb free solder is conducted only on the second surface.
(4) The printed wiring board according to (1), wherein the soldering work employing the Pb free solder is flow soldering or reflow soldering.

According to the invention, the contacts to be used as the switches are formed only on one of the surfaces of the printed circuit, and the electronic components are arranged only on the other surface of the printed board on which the electronic components are mounted, by conducting soldering work employing Pb free solder only on the surface of the printed board on which the electronic components are arranged. Accordingly, the contacts are arranged on the surface at the opposite side to the electronic components, and the flux of the like which is applied on occasion of soldering the electronic components can be restrained from adhering to the contacts. As the results, it is possible to mount the electronic components, while adhesion of the flux or the like to the contacts is restrained, even in case where the Pb free solder is used. It is to be noted that the electronic components herein include connectors.

According to the invention, the LED is inserted into the through hole in such a manner that the light is emitted from the surface on which the contacts are formed, and the soldering work employing the Pb free solder is conducted only on the surface of the printed board on which the LED as the electronic component is arranged. Accordingly, it is possible to emit the light of the LED from the surface on which the contacts are formed, while the electronic components to be soldered are arranged only on the surface of the printed board on which the electronic components are arranged, and therefore, the printed wiring board can be easily incorporated, even in case where a space for installing the printed wiring board is narrow. It is to be noted that the LED is an abbreviate name of a Light Emitting Diode.

According to the invention, the film of strippable solder resist is formed on the contacts, and the soldering work employing the Pb free solder is conducted only on the surface of the printed board on which the electronic components are arranged. Accordingly, even though the flux or the like may come from the surface at the opposite side, it is possible to reliably prevent the flux or the like from adhering to the contacts. Moreover, when the Pb free solder is used, it is necessary to raise the heating temperature because a melting temperature of the Pb free solder is higher than that of the conventional solder which contains the Pb. However, according to the invention, because the contacts are provided on the surface at the opposite side to the surface where the soldering work is conducted, influence due to a rise of the heating temperature is depressed to the least, and it is possible to use the conventional strippable solder resist.

In the above described printed wiring board, the soldering work employing the Pb free solder may be conducted by either of flow soldering and reflow soldering.

According to the invention, it is possible to provide a printed wiring board on which electronic components can be mounted, while adhesion of flux or the like to contacts is restrained, even in case where Pb free solder is used.

### BRIEF DESCRIPTION OF THE DRAWINGS

FIG. 1A is a view showing an A surface of a printed wiring board.

FIG. 1B is a view showing a B surface of the printed wiring board.

FIG. 2 is a sectional view taken along a line C-C of the printed wiring board in FIG. 1B.

FIG. 3 is a sectional view taken along the line C-C of the printed wiring board during production.

FIG. 4 is a sectional view taken along the line C-C of the printed wiring board during the production.

FIG. 5 is a view showing the printed wiring board in a reflow furnace.

FIG. 6 is a sectional view taken along the line C-C of the printed wiring board during the production.

FIG. 7 is a sectional view taken along the line C-C of the printed wiring board during the production.

FIG. 8A is a plan view of a conventional printed wiring board.

FIG. 8B is a sectional view taken along a line D-D of the conventional printed wiring board in FIG. 8A.

### DETAILED DESCRIPTION OF PREFERRED EMBODIMENTS

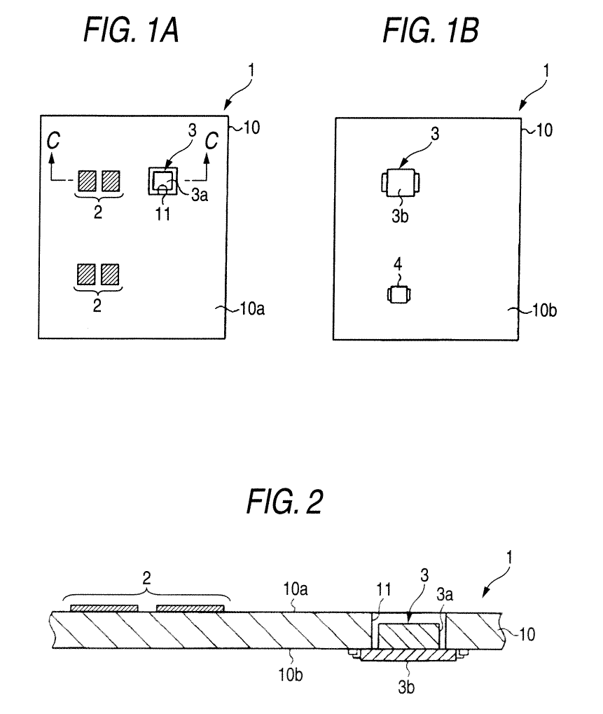

Now an embodiment of the invention will be described referring to FIGS. 1A to 5.

As shown in FIGS. 1A and 1B, a printed wiring board 1 is formed of a board having upper and lower surfaces including an A surface 10a and a B surface 10b, and provided with a through hole 11 in a rectangular shape into which an LED (Light Emitting Diode) 3 is inserted. An electrically conductive layer having an electrically conductive pattern, which is not shown, printed thereon is formed on the A surface 10a of the printed wiring board 1. A part of the electrically conductive layer is exposed as a plurality of (two, in this embodiment) contacts 2, and a light emitting part 3a of the LED 3 is exposed from the through hole 11. A pair of the contacts 2 function as a switch, when they are electrically connected by a conductor, which is not shown. The LED 3 and an electronic component 4, both of which are electronic components, are mounted on the B surface 10b of the printed wiring board 1 by conducting soldering work employing the Pb free solder. The electronic components 3, 4 in this embodiment include connectors. As shown in FIG. 2, the light emitting part 3a of the LED 3 is inserted into the through hole 11 from the B surface 1b, and a driver part 3b of the LED 3 is fixed by soldering to the B surface 10b. In short, the contacts 2 are not provided on the B surface 10b on which the LED 3 and the electronic component 4 to be fixed by soldering are arranged.

This printed wiring board 1 is produced in the following production method. The production method employing the reflow soldering will be described herein.

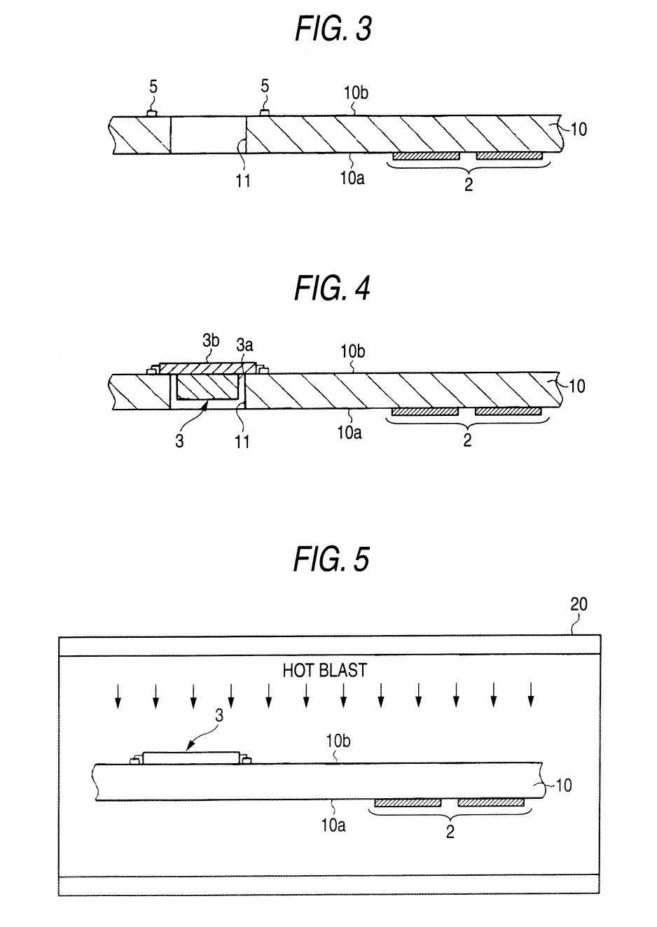

As shown in FIG. 3, the electrically conductive layer on which the electrically conductive pattern is printed with a copper foil is formed on a printed board 10, and the through hole 11 for inserting the LED 3 is formed in the printed board 10. The contacts 2 which function as the switches are exposed from the A surface 10a of the printed board 10. It is to be noted that the contacts 2 which function as the switches are not exposed from the B surface 10b of the printed board 10. The LED 3 and the electronic component 4 are mounted on the printed board 10 which has been so constructed as described above, in the following manner.

As a first step, the printed board 10 is disposed so that the B surface 10b is directed upward. Then, the flux is applied to positions where the LED 3 and the electronic component 4 are arranged on the B surface 10b of the printed board 10, and a Pb free cream solder 5 is printed thereon. In FIG. 3, the cream solder 5 is printed on a region around the through hole 11 of the printed board 10.

Then, as shown in FIG. 4, the LED 3 and the electronic component 4 are disposed on an upper surface of the cream solder 5 on the B surface 10b of the printed board 10, by means of an exclusive injector. In FIG. 4, the light emitting part 3a of the LED 3 is inserted into the through hole 11 from the B surface 10b of the printed board 10, and the driver part 3b of the LED 3 is positioned on the B surface 10b of the printed board 10. Moreover, a connecting terminal of the driver part 3b of the LED 3 is embedded in the cream solder 5.

Thereafter, as shown in FIG. 5, the printed board 10 on which the cream solder 5 has been printed, and the LED 3 and the electronic component 4 are arranged is heated in a reflow furnace 20 in a state where the B surface 10b is directed upward. In this embodiment, the reflow furnace 20 is so constructed that the hot blast is blown only from the above. When the cream solder 5 is heated, the cream solder is cooled and melted. When the cream holder 5 is hardened, the LED 3 and the electronic component 4 are fixed on the B surface 10b of the printed board 10.

In the above described manner, the printed wiring board 1 having the printed board 10 on which the LED 3 and the electronic component 4 are mounted is produced.

According to the embodiment which has been described above, the following operational effects can be achieved.

(1) The contacts 2 which function as the switches are formed only on the A surface 10a of the printed board 10, and the electronic component 4 is arranged only on the B surface 10b of the printed board 10. Then, the soldering work employing the Pb free solder is conducted only on the B surface 10b of the printed board 10 on which the electronic component 4 is arranged, and thus, the electronic component 4 is mounted. Because the contacts 2 are arranged on the A surface 10a at the opposite side to the electronic component 4, the flux or the like which is applied when the electronic component 4 is soldered can be restrained from adhering to the contacts 2. As the results, it is possible to mount the electronic component 4 while restraining the adhesion of the flux or the like to the contacts 2, without using the conventional strippable solder resist.

(2) Because the contacts 2 are provided on the surface (the A surface 10a) at the opposite side to the surface (the B surface 10b) where the soldering work is conducted, the strippable solder resist is not used. Accordingly, it is possible to reduce trouble and cost for forming the strippable solder resist.

(3) The through hole 11 is formed in the printed board 10, and the LED 3 is inserted into the through hole 11 so that light may be emitted from the A surface 10a on which the contacts 2 are formed, and then, the soldering work employing the Pb free solder is conducted on the LED 3 at the side of the B surface 10b of the printed board 10 on which the electronic component 4 is arranged. Therefore, it is possible to emit the light of the LED 3 from the side of the A surface 10a on which the contacts 2 are formed, while the electronic components 3, 4 to be soldered are arranged only on the B surface 10b of the printed board 10. Moreover, because a projecting amount of the LED 3 from the printed board 10 can be depressed, the printed wiring board can be easily incorporated, even in case where a space for installing the printed wiring board is narrow.

The above described embodiment can be appropriately modified as follows.

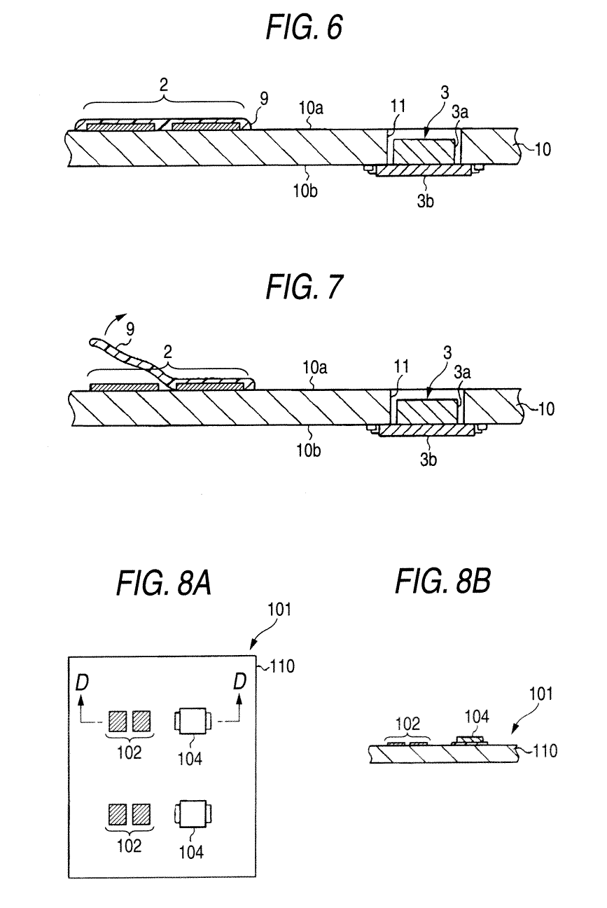

As shown in FIG. 6, it is possible to conduct the soldering work by forming a film of the strippable solder resist 9 on the contacts 2 on the A surface 10a of the printed board 10, before the soldering work employing the Pb free solder is conducted. Specifically, as shown in FIG. 6, the film of the strippable solder resist 9 is formed so as to cover the contacts 2 on the A surface 10a of the printed board 10, before the soldering work is conducted, and the printed board 10 is heated in the reflow furnace 20 in a state where the film of the strippable solder resist 9 has been formed. Then, as shown in FIG. 7, the strippable solder resist 9 is removed by a pair of tweezers or the like, after the cream solder 5 has been hardened.

According to the above described structure, the film of the strippable solder resist 9 is formed on the contacts 2, and the soldering work employing the Pb free solder is conducted only on the B surface 10b of the printed board 10 on which the LED 3 and the electronic component 4 are arranged. Therefore, even though the flux or the like may come from the B surface 10b at the opposite side, it is possible to reliably prevent the flux or the like from adhering to the contacts 2. Moreover, because the contacts 2 are provided on the surface (the A surface 10a) at the opposite side to the surface (the B surface 10b) where the soldering work is conducted, influence due to a rise of the heating temperature is depressed to the least, and it is possible to use the conventional strippable solder resist.

Although the soldering work is conducted by reflow soldering in the above described embodiment, it is also possible to conduct the soldering work by flow soldering. Specifically, the LED 3 and the electronic component 4 are bonded to the B surface 10b of the printed board 10, and the flux is applied to the region where the soldering work is to be conducted. Then, the B surface 10b of the printed board 10 is heated, and soaked in a surface layer of a solder tank which contains the solder in a liquid state, to be brought into contact with the melted solder, whereby the LED 3 and the electronic component 4 are fixed by soldering to the printed board 10.

What is claimed is:

1. A printed wiring board comprising:
a printed board having a first surface and a second surface opposed to the first surface;
contacts which are to be used as switches and are only formed on the first surface; and
an electronic component which is arranged only on the second surface and mounted by conducting soldering work employing Pb free solder on the second surface.

2. The printed wiring board according to claim 1, wherein
the electronic component is an LED,
a through hole is formed through the printed board, and
the LED is inserted into the through hole in such a manner that light is emitted from the first surface.

3. The printed wiring board according to claim 1, wherein a film of strippable solder resist is formed on the contacts.

4. The printed wiring board according to claim 1, wherein the soldering work employing the Pb free solder is flow soldering or reflow soldering.
